(19) United States
(12) Patent Application Publication
(10) Pub. No.: US 2025/0056755 A1
(43) Pub. Date: Feb. 13, 2025

(54) COOLING SHROUD AND ENCLOSURE FOR CONSUMER ELECTRONIC MEMORY DEVICE FOR OPTIMIZED PERFORMANCE THEREOF

(71) Applicant: Advantest Corporation, Tokyo (JP)

(72) Inventors: Justin Glasgow, San Jose, CA (US); Brad Emberger, San Jose, CA (US); Kapil Ayyawar, San Jose, CA (US)

(21) Appl. No.: 18/750,720

(22) Filed: Jun. 21, 2024

Related U.S. Application Data
(60) Provisional application No. 63/531,792, filed on Aug. 9, 2023.

(51) Int. Cl. H05K 7/20; G06F 1/20

(52) U.S. Cl. CPC H05K 7/20136; G06F 1/20; H05K 7/20209

(57) ABSTRACT

Embodiments of the present invention provide memory device (e.g., SSD) enclosures and shrouds that can receive and house SSDs of a specific form factor width, and can advantageously be selectively adapted to house and cool SSDs of a narrower form factor width using an adapter. The SSD shrouds described herein can guide SSDs into the correct position and orientation to be housed by the enclosure for quick and convenient installation, and advantageously redirect the air flow for effective cooling during operation to increase performance of the drive, optionally using internal fins to guide the airflow. Micro fans can be disposed on the top and/or bottom of the enclosure to improve air intake or exhaust. The SSD enclosures and adapters of the present invention obviate the need for differently sized SSD enclosures for specific device form factors and widths, which reduces costs and overhead when running multiple SSDs.

### CROSS-REFERENCE TO RELATED APPLICATIONS

This application claims priority and benefit of provisional patent application Ser. No. 63/531,792 Attorney Docket Number ATSY-0136-00.00US, with filing date Aug. 9, 2023, and is related to co-pending patent application Ser. No. 18/443,184 Attorney Docket Number ATSY-0134-01U0US, with filing date Feb. 15, 2024, both of which are incorporated by reference in their entirety.

### FIELD

Embodiments of the present invention generally relate to the field of memory devices. More specifically, embodiments of the present invention relate to the thermal management of consumer electronic memory devices.

### BACKGROUND

A Solid-State Drive (SSD) is a type of storage device used in computers and other electronic devices to store and retrieve data. Unlike traditional hard disk drives (HDDs), which use spinning magnetic disks and mechanical read/write heads to access data, SSDs use non-volatile memory, typically NAND flash memory, to store data. Flash memory typically consists of a grid of memory cells that can be electrically programmed and erased to store and retrieve data and a controller that manages the operations of the SSD. The SSD connects to a host system through an interface, such as SATA (Serial ATA), PCIe (Peripheral Component Interconnect Express), or NVMe (Non-Volatile Memory Express). Different interfaces provide different speeds and bandwidths for transferring data between the SSD and the computer.

Compared to mechanical HDDs, newer memory devices like SSDs offer faster data access times, lower power consumption, quieter operation (no moving parts), improved durability (resistant to shock and vibration), and generally smaller form factors. SSDs have become increasingly popular as a primary storage solution in consumer applications, such as desktops, laptops, servers, and other devices that require fast and reliable data storage and retrieval. These drives come in form factors of different sizes (e.g., 3.5 in, 2.5 in, etc.) and different form factor widths (e.g., wide or narrow). Also, SSD devices have a temperature range that provides the device with optimal performance.

Memory devices such as SSDs often generate a significant amount of heat during operation, and the heat can negatively impact performance of the SSD when temperatures within the device increase significantly. For example, as data is read from or written to the NAND flash memory chips inside the SSD, electrical currents flow through the chips, leading to resistance and generating heat. Moreover, because SSDs are typically designed to be small and compact, with few or no moving parts, effective thermal management can be challenging, as there is limited surface area for heat to escape. As such, high-performance SSDs, or SSDs subjected to heavy workloads for extended periods, may experience increases in temperature outside the optimum performance temperature range that significantly impact their performance. In some cases, an SSD may fail completely when the drive overheats, and data stored on the drive may be corrupted or lost.

Beyond SSDs, other types of memory and storage devices experience similar heat limitations that can be managed by cooling systems and dedicated enclosures. To prevent overheating, some memory and storage devices, such as SSDs and HDDs, incorporate thermal management techniques, such as heat sinks, thermal pads, temperature sensors, etc. However, these techniques typically fail to bring the devices to an optimal temperature during heavy use, which impacts performance of the device and potentially the useful lifetime of the device. Accordingly, a more effective approach to thermal management of SSDs and other memory and storage devices is desired.

### SUMMARY

Accordingly, embodiments of the present invention provide a device enclosure with active cooling mechanisms that effectively cool a memory or storage device disposed within the enclosure during operation to bring the device within an optimal thermal range for increased performance and to prevent overheating during heavy use. Moreover, the device enclosure can accommodate memory devices of different form factors and different widths, such as narrow and wide form factor widths of 2.5 in or 3.5 in drives (e.g., E3.S, U.2, etc.). While the embodiments described herein are described in the context of consumer electronic SSDs, the teachings are also applicable to other forms of memory and storage devices, such as hard disk drives (HDDs) (e.g., magnetic plate drives). According to some embodiments, micro fans disposed at the top and/or bottom of a shroud or enclosure force air over surfaces of the memory device to further improve cooling performance.

According to one disclosed embodiment, an apparatus for housing and cooling a memory device is disclosed. The apparatus includes a device shroud operable to receive the memory device and to guide air over the memory device to cool the memory device during operation thereof, and a cooling system including a first fan disposed on a bottom surface of the device shroud and operable to blow air into the device shroud, the air is guided over a surface of the memory device by the device shroud, and a second fan disposed on a top surface of the device shroud and operable to blow the air out of the device shroud.

According to some embodiments, the device shroud is further operable to receive a memory device including one of: a double-width device, and a single-width device with a device adapter.

According to some embodiments, the single-width device includes an E3.S 1T device, and the double-width device includes an E3.S 2T device.

According to some embodiments, the apparatus includes a device housing operable to house the device shroud, the device housing includes: a display device operable to display a temperature of the memory device, and a plurality of user control inputs operable to control operation of the cooling system.

According to some embodiments, the memory device includes a temperature sensor, and the cooling system is operable to cool the memory device according to a measurement of the temperature sensor.

According to some embodiments, the device shroud includes electrostatic discharge (ESD) materials.

According to some embodiments, the device shroud is 3D printed.

According to some embodiments, the memory device includes a solid state drive (SSD).

According to another embodiment, an apparatus for housing and cooling a memory device is disclosed. The apparatus includes a device shroud operable to receive the memory device and to guide air over the memory device to cool the memory device during operation thereof, a front of the device shroud includes an opening operable to intake air from outside the device shroud, and the device shroud includes internal fins operable to guide air longitudinally along the memory device, and a cooling system including a first fan disposed on a first surface of the device shroud and operable to blow air out of the device shroud, and a second fan disposed on a second surface of the device shroud and operable to blow air out of the device shroud.

According to some embodiments, the device shroud is further operable to receive a memory device including one of: a double-width device, and a single-width device with a device adapter.

According to some embodiments, the single-width device is approximately 7.5 mm wide, and the double-width device is approximately 16.8 mm wide.

According to some embodiments, the apparatus includes a device housing operable to house the device shroud, the device housing includes: a display device operable to display a temperature of the memory device, and a plurality of user control inputs operable to control operation of the cooling system, and further the first surface is a top surface and the second surface is a bottom surface.

According to some embodiments, the memory device includes a temperature sensor, and the cooling system is operable to cool the memory device according to a measurement of the temperature sensor.

According to some embodiments, the device shroud includes electrostatic discharge (ESD) materials.

According to some embodiments, the device shroud is 3D printed.

According to some embodiments, the memory device includes a solid state drive (SSD).

According to a different embodiment, a consumer electronic product for housing and cooling a memory device is disclosed, including a housing having a display device operable to display a temperature of the memory device and a plurality of user control buttons, a device shroud disposed within the housing and operable to secure the memory device within the housing and to guide air over a surface of the memory device to cool the memory device during operation, and a cooling system operable to cool the memory device according to input received via the user control buttons. The cooling system includes a first fan disposed on a top surface of the housing, and a second fan disposed on a bottom surface of the housing, the first and second fans are operable to cool the memory device during operation thereof.

According to some embodiments, the device shroud and the housing include a front air intake, the first fan is further operable to blow air upward and out of the device shroud, the second fan is further operable to blow air downward and out of the device shroud, the first fan and second fan are further operable to exhaust hot air out of the device shroud to cool the memory device, and the device shroud includes internal fins operable to guide air longitudinally along the memory device.

According to some embodiments, the first fan is further operable to blow air upward and out of the device shroud to exhaust hot air, and the second fan is further operable to blow air upward and into the device shroud to cool the memory device.

According to some embodiments, the device shroud is further operable to receive a memory device including one of: a double-width device, and a single-width device with a device adapter.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1A is a diagram of an isometric view of an exemplary device enclosure and cooling system for operating a memory hardware device according to embodiments of the present invention.

FIG. 1B is a diagram of a front view of an exemplary device enclosure and cooling system for operating a memory hardware device according to embodiments of the present invention.

FIG. 2 is a diagram showing exemplary air flow of a device enclosure for housing and cooling a consumer memory or other hardware storage device according to embodiments of the present invention.

FIG. 3A is a diagram of an isometric view of an exemplary device enclosure for housing and cooling a consumer memory or other hardware storage device using a device adapter according to embodiments of the present invention.

FIG. 3B is a diagram of a front view of an exemplary device enclosure for housing and cooling a consumer memory or other hardware storage device using a device adapter according to embodiments of the present invention.

FIG. 4 depicts exemplary air flow diagram of an exemplary device enclosure for housing and cooling a consumer memory or other hardware storage device using a device adapter according to embodiments of the present invention.

FIG. 5 depicts an exploded view of individual components of an exemplary device enclosure and device adapter for housing and cooling a consumer memory or other hardware storage device according to embodiments of the present invention.

FIG. 6 depicts an exemplary SSD enclosure having a cooling system that utilizes a piezoelectric air moving element enclosed by housing without using separate fans to cool the SSD according to embodiments of the present invention.

FIG. 7A is a schematic diagram of an exemplary empty device shroud or enclosure for housing and cooling memory devices according to embodiments of the present invention.

FIG. 7B is a schematic diagram showing a side view of an exemplary empty device shroud or enclosure for housing and cooling memory devices from, according to embodiments of the present invention.

FIG. 7C depicts an internal air flow diagram of an exemplary device cooling enclosure according to embodiments of the present invention.

FIG. 8A is a schematic diagram of an exemplary empty device shroud or enclosure with front air intake for housing and cooling devices according to embodiments of the present invention.

FIG. 8B is a schematic diagram showing a side view of an exemplary empty device shroud or enclosure with front air intake for housing and cooling devices according to embodiments of the present invention.

FIG. 8C depicts an internal air flow diagram of exemplary device enclosure according to embodiments of the present invention.

FIG. 9 is a diagram of an isometric view of an exemplary device enclosure and cooling system for operating a memory hardware device using top-mounted and bottom-mounted fans according to embodiments of the present invention.

### DETAILED DESCRIPTION

Reference will now be made in detail to several embodiments. While the subject matter will be described in conjunction with the alternative embodiments, it will be understood that they are not intended to limit the claimed subject matter to these embodiments. On the contrary, the claimed subject matter is intended to cover alternative, modifications, and equivalents, which may be included within the spirit and scope of the claimed subject matter as defined by the appended claims.

Furthermore, in the following detailed description, numerous specific details are set forth in order to provide a thorough understanding of the claimed subject matter. However, it will be recognized by one skilled in the art that embodiments may be practiced without these specific details or with equivalents thereof. In other instances, well-known methods, procedures, components, and circuits have not been described in detail as not to unnecessarily obscure aspects and features of the subject matter.

Portions of the detailed description that follows are presented and discussed in terms of a method. Although steps and sequencing thereof are disclosed in a figure herein describing the operations of this method, such steps and sequencing are exemplary. Embodiments are well suited to performing various other steps or variations of the steps recited in the flowchart of the figure herein, and in a sequence other than that depicted and described herein.

Some portions of the detailed description are presented in terms of procedures, steps, logic blocks, processing, and other symbolic representations of operations on data bits that can be performed on computer memory. These descriptions and representations are the means used by those skilled in the data processing arts to most effectively convey the substance of their work to others skilled in the art. A procedure, computer-executed step, logic block, process, etc., is here, and generally, conceived to be a self-consistent sequence of steps or instructions leading to a desired result. The steps are those requiring physical manipulations of physical quantities. Usually, though not necessarily, these quantities take the form of electrical or magnetic signals capable of being stored, transferred, combined, compared, and otherwise manipulated in a computer system. It has proven convenient at times, principally for reasons of common usage, to refer to these signals as bits, values, elements, symbols, characters, terms, numbers, parameters, or the like.

It should be borne in mind, however, that all of these and similar terms are to be associated with the appropriate physical quantities and are merely convenient labels applied to these quantities. Unless specifically stated otherwise as apparent from the following discussions, it is appreciated that throughout, discussions utilizing terms such as “accessing,” “writing,” “including,” “storing,” “transmitting,” “associating,” “identifying,” “encoding,” “labeling,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Some embodiments may be described in the general context of computer-executable instructions, such as program modules, executed by one or more computers or other devices. Generally, program modules include routines, algorithms, programs, objects, components, data structures, etc. that perform particular tasks or implement particular abstract data types. Typically the functionality of the program modules may be combined or distributed as desired in various embodiments.

### Memory Device Cooling Enclosure and Adapter

Embodiments of the present invention provide enclosures and shrouds that can receive and house memory or storage devices (e.g., solid state drives (SSDs)) of a specific form factor width (e.g., E3.S 2T, etc.,) and can advantageously be selectively adapted to house and cool devices of a narrower form factor width (e.g., E3.S 1T) using an adapter. While the embodiments described herein are described in the context of SSDs, the teachings are also applicable to other forms of memory and storage devices, such as memory modules, flash memory, hard disk drives (HDDs) (e.g., magnetic plate drives) that can be housed and cooled by the device enclosures described herein. Some embodiments described herein are well suited to cool consumer electronic SSD devices. According to some embodiments, micro fans disposed at the top and/or bottom of a shroud or enclosure force air over surfaces of the memory device to further improve cooling performance.

The device shrouds described herein can guide SSDs and other memory devices into the correct position and orientation to be housed by the enclosure for quick and convenient installation, and advantageously redirect the air flow for effective cooling during operation to increase performance of the drive. By accommodating SSDs of different form factors, the SSD enclosures, shrouds, and adapters of the present invention obviate the need for differently sized SSD enclosures for specific device form factors and widths, which reduces costs and overhead when running multiple SSDs.

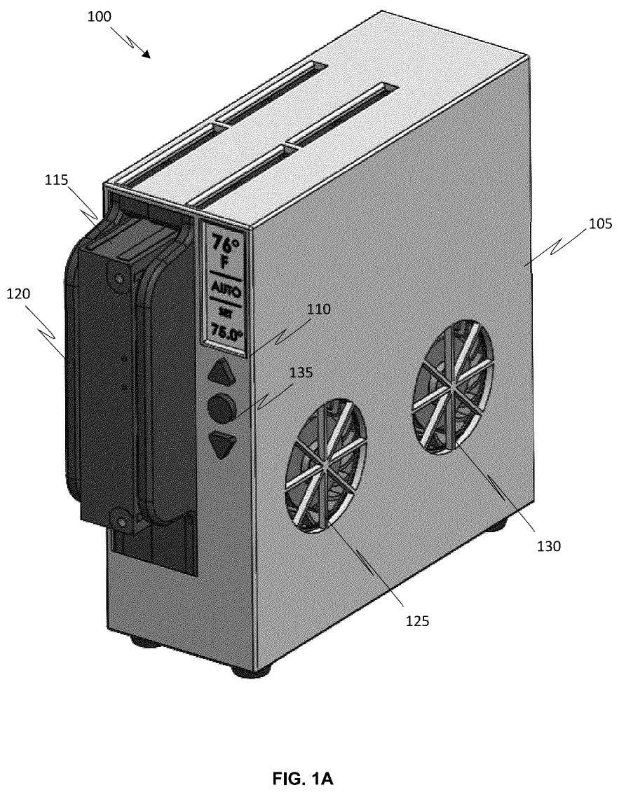

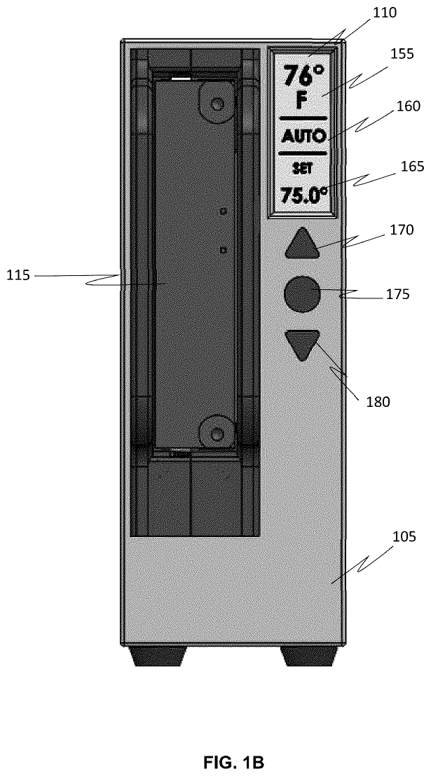

FIG. 1A is an isometric view depicting an exemplary device enclosure 100 for housing and cooling a consumer memory or other hardware storage device according to embodiments of the present invention. Enclosure housing 105 is operable to house a device of a certain form factor (e.g., a “wide” or “double-wide” form factor) using a device shroud 120 that secures the device and directs cold air over surfaces thereof. The shroud 120 within enclosure housing 105 can be adapted to house and cool a device of a narrower form factor (e.g., a “narrow” or “single-wide” form factor) using a separate adapter component according to embodiments. In the example of FIG. 1A, enclosure housing 105 houses a consumer memory device 115, such as an SSD, using device shroud 120 to secure device 115 in place and cool the device using an active cooling system including fans 125 and 130, which are typically relatively small variable speed fans. According to some embodiments, only a single fan is used. The embodiment of FIG. 1 is intended to be used by a consumer of the SSD during normal operation of the SSD to provide system cooling to enhance the performance of the SSD. The example of FIG. 1 shows a double-wide storage device 115 installed in enclosure housing 105 (without using an adapter). The housing 105, the shroud 120, and the adapter (not pictured) can be made of a 3D printed material. According to some embodiments, the components are made from electrostatic discharge (ESD) materials.

A display 110 is disposed on the face of enclosure housing 105 and coupled to a cooling system having control circuits for activating fans 125 and 130 and controlling the speed of fans 125 and 130. A temperature sensor/thermostat internal to housing 105 measures real-time temperatures of the device so that the device can be cooled by the cooling system to a desired temperature or range of temperatures during normal operational use of the SSD. The cooling system can also include a piezoelectric membrane and/or a compressed dry air manifold, and optionally includes buttons 135 for adjusting the cooling system to a specific temperature, or to change an operating mode of the cooling system (e.g., On, Off, Auto, etc.). The cooling system of FIG. 1A is advantageous because SSDs operate at optimal performance within prescribed temperature levels, and effective cooling increases the performance and lifetime of the SSD in its normal (e.g., consumer-level) operation.

FIG. 1B shows a front view of exemplary SSD enclosure 100 according to embodiments of the present invention. Cooling system display 110 displays the current device temperature 155 as measured by an internal temperature probe or thermostat, the current operating mode 160 of the cooling system, and the temperature 165 that the cooling system is configured to achieve (the “set temperature”). A user can interact with the cooling system by pressing buttons 170, 175, and 180. Up button 170 and down button 180 can be used to increase or decrease the set temperature 165, the fan speed, etc., and mode button 175 toggles between different operating modes of the cooling system, such as On, Off, and Automatic. Operating in the On mode keeps the cooling system running regardless of the current device temperature 155. In this mode, up button 170 and down button 180 can be used to increase and decrease the fan speed, according to some embodiments. The Off mode turns off the cooling system completely. Automatic mode modulates fans 125 and 130 (shown in FIG. 1A) to efficiently reach the set temperature 165, and up button 170 and down button 180 operate to adjust the set temperature 165.

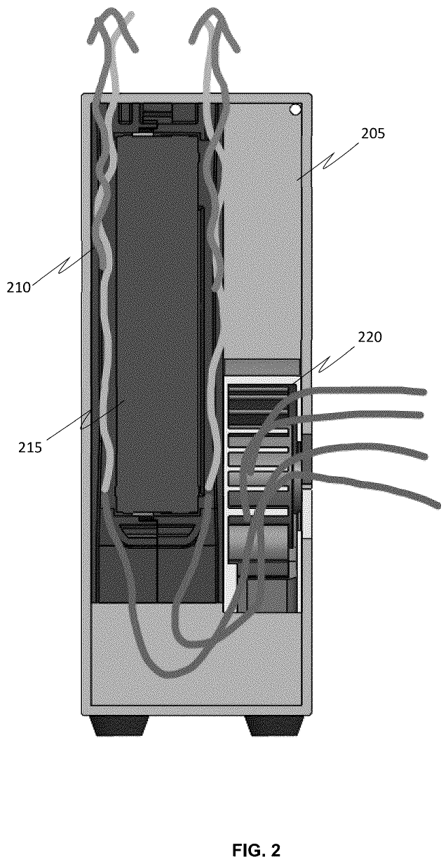

FIG. 2 depicts an air flow diagram of an exemplary device enclosure 205 for housing and cooling a consumer memory or other hardware storage device according to embodiments of the present invention. As depicted in the example of FIG. 2, air from outside enclosure 205 is drawn into the enclosure by fans 220, and the air is guided over the surfaces of device 215 by shroud 210, which secures device 215 within enclosure 205. The air cools device 215 during operation and flows out of the top of enclosure 205 to exhaust the air into the environment as new air is drawn into enclosure 205. In the example of FIG. 2, device 215 is a double-width SSD that is secured by enclosure 210 without using an adapter. According to some embodiments, shroud 210 includes ducts, channels, or other physical elements (e.g., fins, deflectors, etc.) to promote optimal air movement through the enclosure.

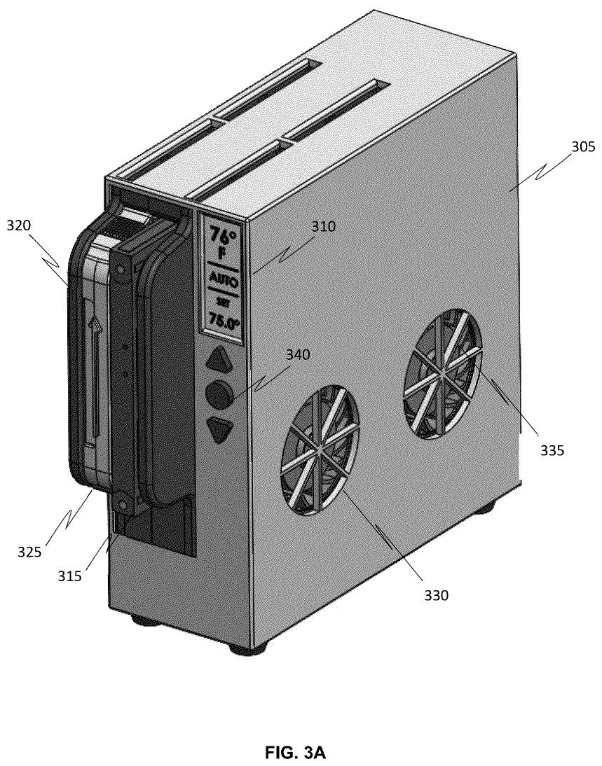

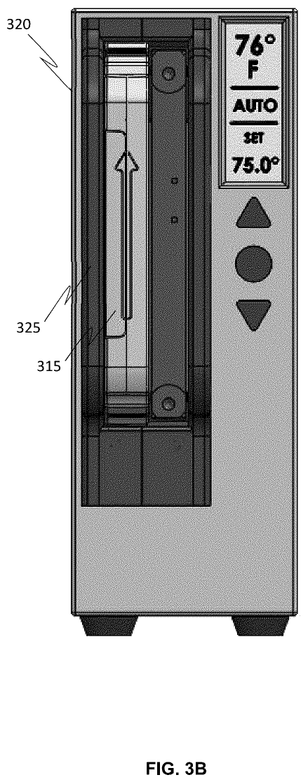

FIG. 3 depicts an exemplary device enclosure 305 for housing and cooling a consumer memory or other hardware storage device using a device adapter according to embodiments of the present invention. FIG. 3A depicts enclosure 305 from an isometric perspective, and FIG. 3B depicts enclosure 305 from a front perspective. In the example of FIG. 3, enclosure 305 is adapted to house and cool a device of a narrow form factor (e.g., a single-wide form factor) using an adapter 325. In the example of FIG. 3, enclosure 305 houses a consumer memory device 315, such as a solid-state drive (SSD), using device shroud 320 in conjunction with device adapter 325 to secure the device in place and cool the device using an active cooling system 310 including fans 330 and 335. The system of FIG. 3A is intended to be used by a consumer of the SSD during normal operation of the SSD to provide system cooling to enhance the performance of the SSD. The example of FIG. 3 shows a single-width device 315 installed in enclosure 305 using adapter 325. Adapter 325 can be removed so that enclosure 305 can house and cool a storage device of a wider form factor.

The cooling system 310 includes control circuits for activating fans 330 and 335 and for controlling the speed of fans 330 and 335, and a temperature sensor/thermostat that measures real-time temperatures of the device so that the device can be cooled to a desired temperature or range of temperatures during normal operational use of the SSD. Cooling system 310 can also include a piezoelectric cooling system, compressed dry air, etc., and optionally includes buttons 340 for adjusting the cooling system 310 to a desired temperature, or to change an operating mode of cooling system 310 (e.g., On, Off, Auto, etc.). The cooling system of FIG. 3A is advantageous because SSDs operate at optimal performance within prescribed temperature levels. Further, the cooling system increases the performance and lifetime of the SSD in its consumer-based operation.

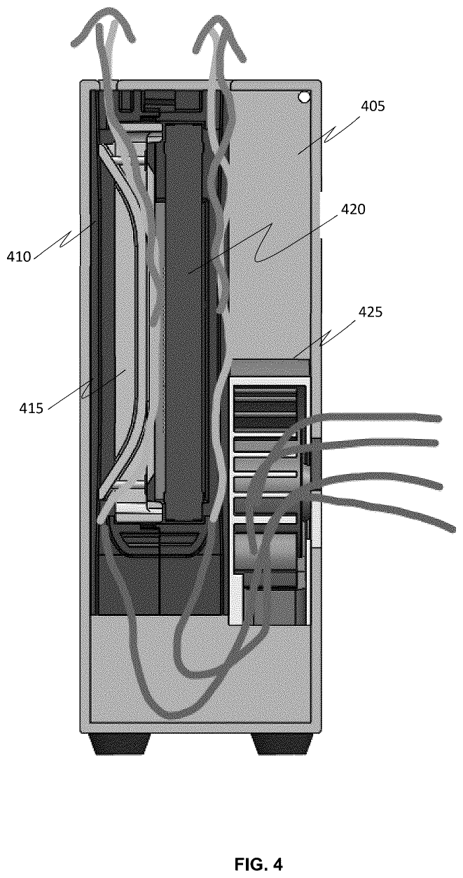

FIG. 4 depicts an air flow diagram of an exemplary device enclosure 405 for housing and cooling a consumer SSD or other similar hardware storage device using an adapter according to embodiments of the present invention. As depicted in the example of FIG. 4, air from outside enclosure 405 is drawn into the enclosure by fans 425, and the air is guided over the surfaces of SSD 420 by shroud 410 in conjunction with adapter 415, which is secured to shroud 410 by tension and optionally interlocking members. The air flow generated by fans 425 cools device 420 during operation and flows out of the top of enclosure 405 to exhaust the air into the environment as new air is drawn into enclosure 405. In this way, SSD 420 can operate at an optimum temperature to improve performance of memory operations performed using SSD 420 without any risk of overheating.

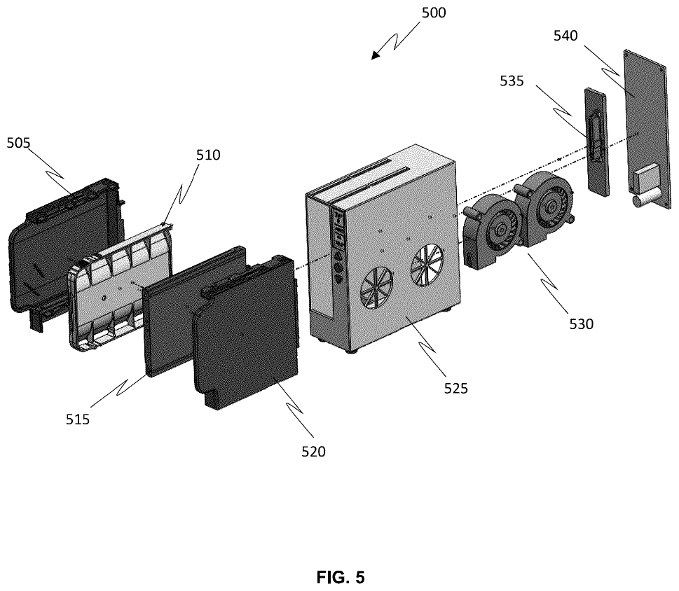

FIG. 5 depicts an exploded view of individual components of an exemplary SSD enclosure 500 and SSD adapter 510 for housing and cooling a consumer memory or other hardware storage device according to embodiments of the present invention. Enclosure housing 525 houses a consumer memory storage device 515, such as a solid-state drive (SSD), and cools the device using an active cooling system including variable speed fans 530. Enclosure housing 525 is operable to receive back panel 540 to substantially enclose housing 525 once the components disposed inside the enclosure housing 525 are in place. A device shroud for securing the device in place is depicted in two separate components, a left shroud component 505 and a right shroud component 520, which can be connected to enclose device 515 within device housing 525, and can guide air over the surfaces of storage device 515 to cool device 515 during operation. A device adapter 510 can be secured to the device shroud for use with a narrow form factor width device. The device shroud can also be used to secure a wide form factor width within housing 525 without using adapter 510. The system of FIG. 5 is intended to be used by a consumer of device 515 during normal operation of device to provide system cooling to enhance the performance of the device. Circuit board 535 includes an on-board controller that interfaces with storage device 515 and a computer system via USB or the like to receive commands and data from the computer system to store and/or retrieve data from storage device 515, for example.

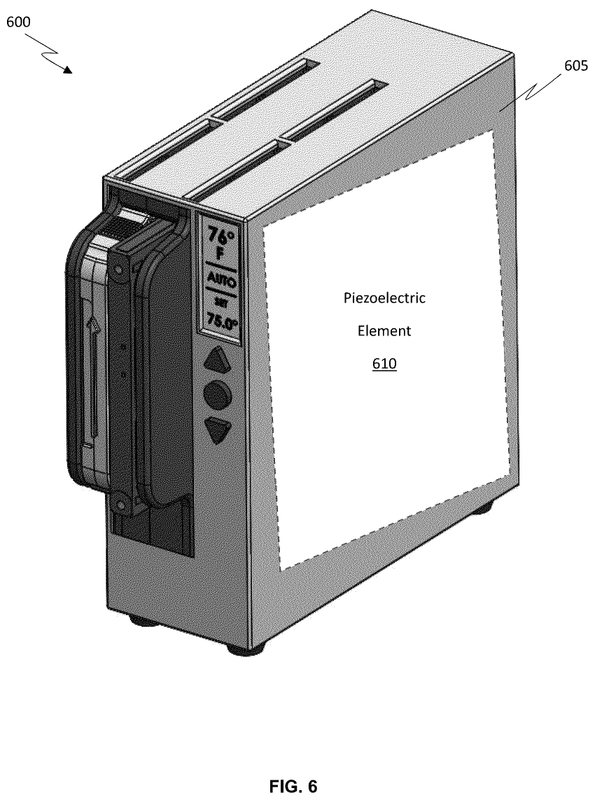

FIG. 6 depicts an exemplary SSD enclosure 600 having a cooling system that utilizes a piezoelectric air moving element (e.g., membrane) 610 enclosed by housing 605 without using separate fans to cool the SSD according to embodiments of the present invention. Piezoelectric air moving element 610 can be a one-way membrane/valve that pulsates at high speed to create a pressure imbalance that causes air to move in one direction. Advantageously, the piezoelectric air moving element 610 requires less footprint than traditional fans, so the enclosure 600 can be more compact, as no fans are required.

Memory Device Cooling Shroud with Integrated Fans

Some embodiments of the present invention provide a device cooling shroud that can receive and house memory devices (e.g., consumer electronic SSD devices) of a specific form factor width (e.g., E3.S 2T), and can advantageously be selectively adapted to house and cool memory devices of a narrower form factor width (e.g., E3.S 1T). The device shrouds described herein guide the memory device into the correct position and orientation to be received by the test system for quick and convenient installation, and advantageously redirect the air flow to the narrower form factor for effective cooling during testing or during normal operation thereof in the case of a consumer electronic memory device. The device shrouds can be used in conjunction with a computer system enclosure, server, rack, hard drive enclosure or the like, as well as device interface boards (DIBs) and similar components used to test memory devices and computer hardware using active cooling systems. By adapting to devices of different form factors, the device shroud of the present invention advantageously obviates the need for specific device shrouds for different device form factors.

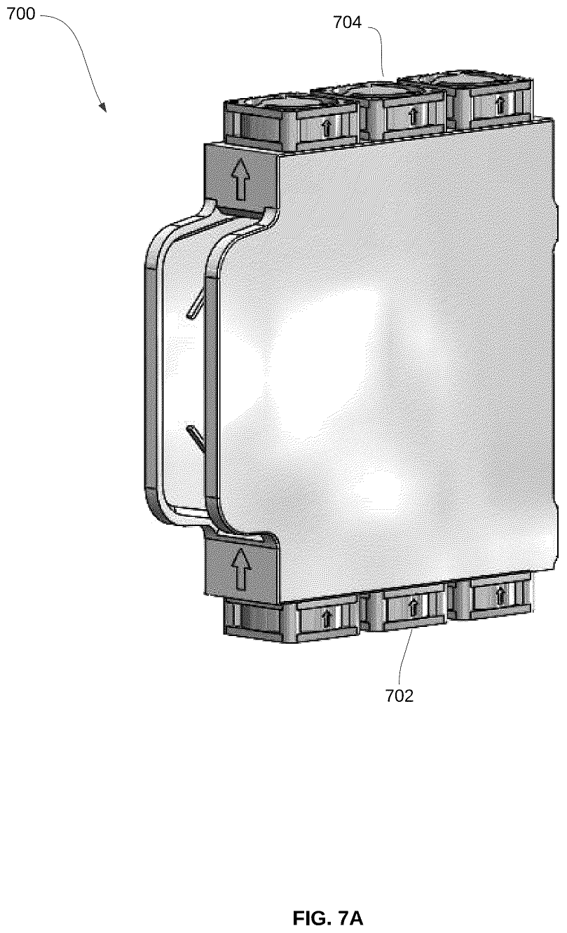

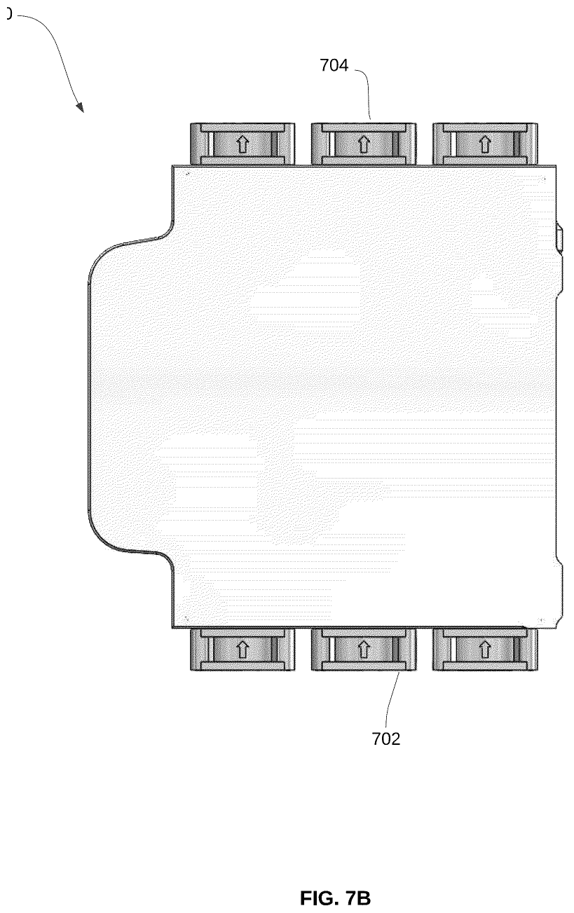

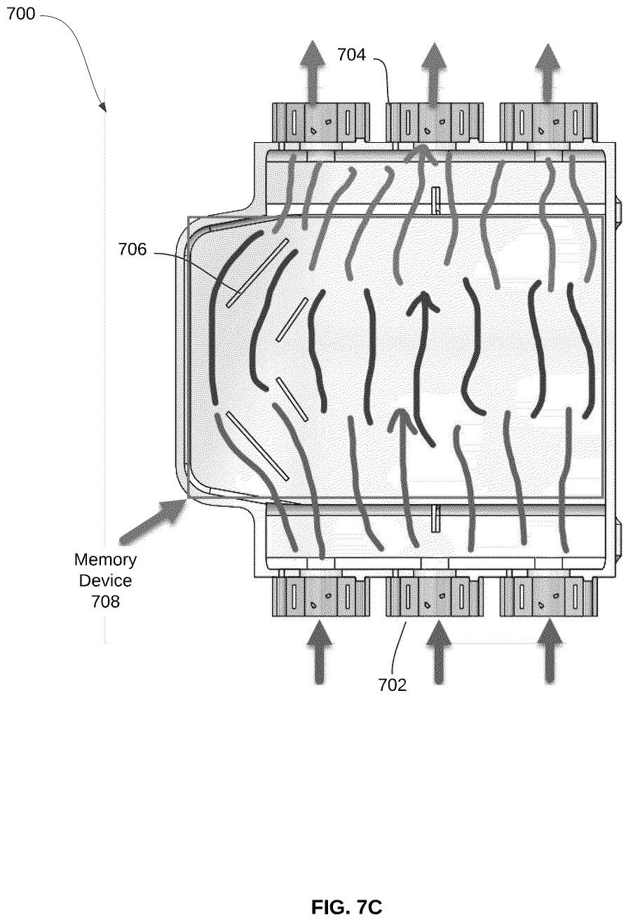

FIG. 7A is a schematic diagram of an exemplary empty device shroud 700 for housing and cooling devices according to embodiments of the present invention. Device shroud or cooling shroud 700 can house a double-width memory device and can advantageously house a single-width memory device when used with a device adapter (e.g., adapter 325 depicted in FIG. 3). FIG. 7B shows shroud 700 from a side view, according to embodiments of the present invention. The single-width device can be 7 or 7.5 mm, and the double-width device can be 15 or 16.8 mm wide consumer memory devices, for example, according to different form factors.

Shroud 700 is used in conjunction with a forced air-cooling system that blows cold air over surfaces of a memory device 708 (FIG. 7C) during testing. In the example of FIG. 7A, cooling shroud 700 includes bottom-mounted vertically oriented fans 702 to intake air, and top-mounted vertically oriented fans 704 that exhaust the air out of the top of shroud 700 to cool memory device 708 housed within. Fans 702 and 704 can be micro axial fans 25 mm or 40 mm wide, for example. The front side of device shroud 700 is closed/sealed to prevent air from leaking out of the front side, and routes air over surfaces of memory device 708 for efficient cooling. The air can be provided to device shroud 700 by air ducts, tubes, cooling channels, etc., and can be used in conjunction with temperature sensors to achieve a desired temperature or range of temperatures during testing. Of course, fewer or additional fans can be used, according to embodiments. Using more fans can be advantageous as redundancy in case a fan malfunctions during device operation to prevent damage to the device or system failure, data loss, etc. According to some embodiments, additional fans are included by stacking fans on top of one another to increase backpressure. To stack the fans, shrouded spacers can be included between the fans for stability and/or to dampen vibrations thereof.

FIG. 7C depicts an internal air flow diagram of exemplary device shroud 700 according to embodiments of the present invention. Air from outside shroud 700 is drawn into the shroud by fans 702 and, and the air is guided over the surfaces of shroud 700 (and any device 708 enclosed therein) by internal fins 706 which direct airflow upward as indicated in the figure. The air cools the enclosed memory device 708 during operation thereof and is blown out of the top of shroud 700 by fans 704 to exhaust the air into the environment as new air is drawn into shroud 700.

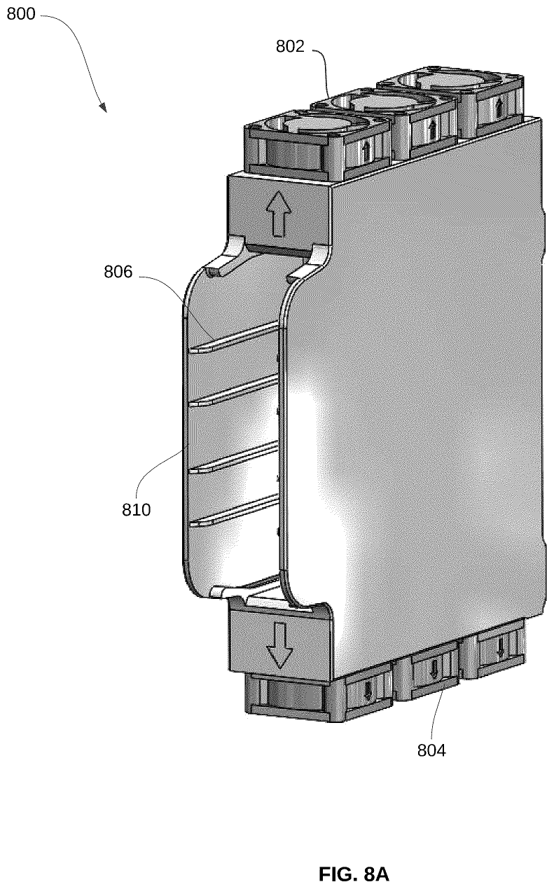

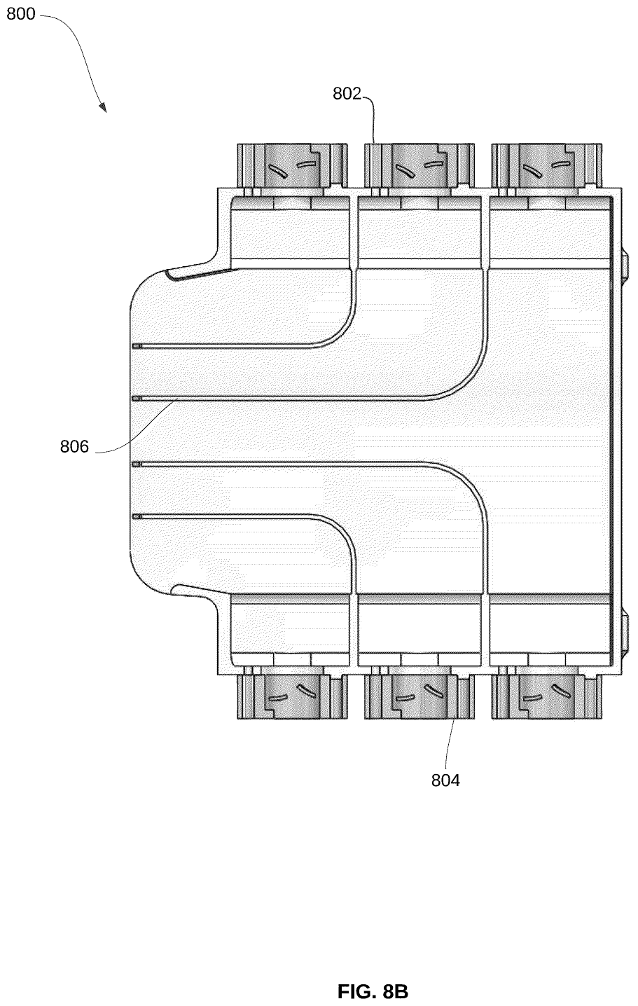

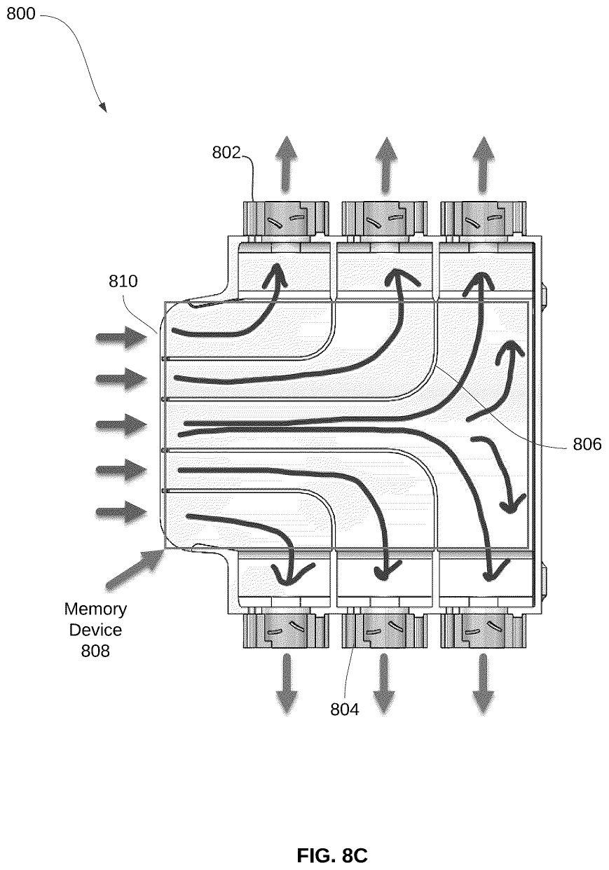

FIG. 8A is a schematic diagram of an exemplary empty device shroud or shroud 800 with front air intake for housing and cooling devices (e.g., consumer memory devices) according to embodiments of the present invention. Device shroud or cooling shroud 800 can house a double-width device, and can advantageously house a single-width device when used with a device adapter. FIG. 8B shows shroud 800 from a side view, according to embodiments of the present invention.

Device shroud 800 is used in conjunction with a forced air-cooling system that blows cold air over surfaces of a device (e.g., device 808 of FIG. 8C) during testing or normal operation thereof. Front air intake may be especially advantageous for devices with longitudinally-oriented heat sinks that benefit from a similarly oriented airflow (as opposed to perpendicular flow). For example, this configuration is common on E.1 form factor memory devices.

Integrated fins 806 (FIG. 8A) steer/vector the air draw in through to either side of the memory device, and vertically oriented fans 802 and 804 exhaust air out of the top and bottom of shroud 800, respectively. Air from outside shroud 800 is drawn in through the front 810 of shroud 800 to cool memory device 808 (FIG. 8C) housed within. Fans 802 and 804 can be micro axial fans, for example. The air can be provided to device shroud 800 by air ducts, tubes, cooling channels, etc., and can be used in conjunction with temperature sensors to achieve a desired temperature or range of temperatures during testing or during normal operation of the memory device 808. Of course, fewer or additional fans can be used, according to embodiments. Using more fans can be advantageous as redundancy in case a fan malfunctions during device operation to prevent damage to the device or system failure, data loss, etc. According to some embodiments, additional fans are included by stacking fans on top of one another to increase backpressure. To stack the fans, shrouded spacers can be included between the fans for stability and/or to dampen vibrations thereof.

FIG. 8C depicts an internal air flow diagram of exemplary device shroud 800 according to embodiments of the present invention. Air from outside shroud 800 is drawn into the front 810 of the shroud, and the air is guided over the surfaces of shroud 800 (and any memory device 808 enclosed therein) by fins 806 which direct airflow substantially longitudinally (e.g., parallel to the device 808) across the enclosed memory device 808 (or a heatsink thereof) before exhausting out of the top and bottom of shroud 800.

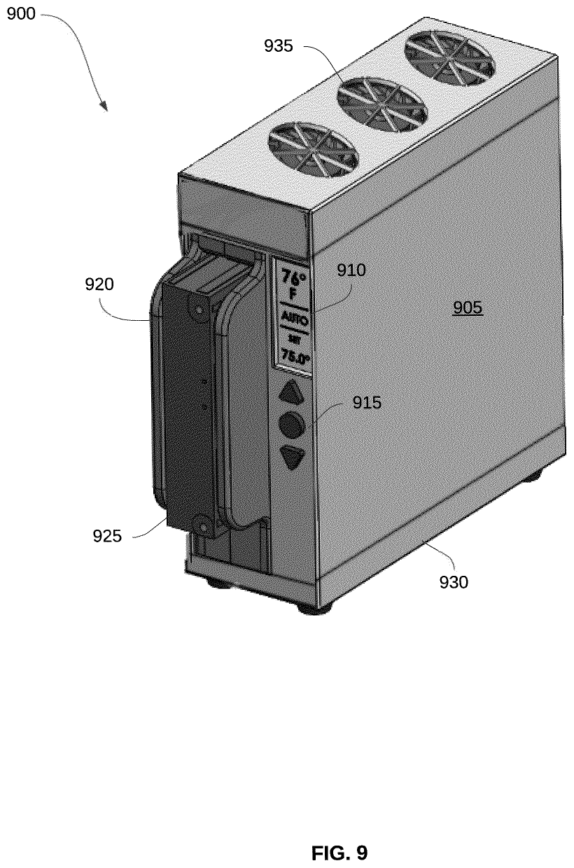

FIG. 9 is an isometric view depicting an exemplary device enclosure 900 for housing and cooling a consumer memory or other hardware storage device using top and/or bottom mounted fans (e.g., micro axial fans) according to embodiments of the present invention. Enclosure housing 905 is operable to house a device of a certain form factor (e.g., a “wide” or “double-wide” form factor) using a device shroud 920 that secures the device and directs cold air over surfaces thereof. The shroud 920 within enclosure housing 905 can be adapted to house and cool a device of a narrower form factor (e.g., a “narrow” or “single-wide” form factor) using a separate adapter component according to embodiments. In the example of FIG. 9, enclosure housing 905 houses a consumer memory device 925, such as an SSD, using device shroud 920 to secure device 925 in place and cool the device using an active cooling system including top-mounted fans 935 and bottom mounted fans 930, which are typically relatively small variable speed fans. Typically one to three fans are mounted to the top and bottom of housing 905, although more fans can be used according to some embodiment. According to other embodiments, only a single fan (top or bottom) is used. The embodiment of FIG. 9 is intended to be used by a consumer of the SSD during normal operation of the SSD to provide system cooling to enhance the performance of the SSD (or similar memory device). The example of FIG. 9 shows a double-wide storage device 925 installed in enclosure housing 905 (without using an adapter). The housing 905, the shroud 920, and the adapter (not pictured) can be made of a 3D printed material. According to some embodiments, the components are made from electrostatic discharge (ESD) materials.

A display 910 is disposed on the face of enclosure housing 905 and coupled to a cooling system having control circuits for activating fans 930 and 935 and controlling the speed of fans 930 and 935. A temperature sensor/thermostat internal to housing 905 measures real-time temperatures of the device so that the device can be cooled by the cooling system to a desired temperature or range of temperatures during normal operational use of the SSD. The cooling system can also include a piezoelectric membrane and/or a compressed dry air manifold, and optionally includes user control buttons (user inputs) 915 for adjusting the cooling system to a specific temperature, or to change an operating mode of the cooling system (e.g., On, Off, Auto, etc.). The cooling system of FIG. 9 is advantageous because SSDs operate at optimal performance within prescribed temperature levels, and effective cooling increases the performance and lifetime of the SSD in its normal (e.g., consumer-level) operation.

According to some embodiments, air from outside enclosure 900 is drawn into the enclosure by fans 930 and, and the air is guided over the surfaces of shroud 920 (and any device 925 enclosed therein) by internal fins which direct airflow upward (see FIG. 7C). The air cools the enclosed memory device 925 during operation thereof and is blown out of the top of housing 905 by fans 935 to exhaust the air into the environment as new air is drawn into housing 905.

According to some embodiments, Air from outside enclosure 900 is drawn into the front of the enclosure, and the air is guided over the surfaces of shroud 920 (and any device 925 enclosed therein) by fins which direct airflow substantially longitudinally (e.g., parallel to the device 925) across the enclosed memory device 925 (or a heatsink thereof) before exhausting out of the top and bottom of housing 905 (see FIG. 8C).

In sum, the disclosed techniques overcome the limitations of traditional methods by providing a flexible and adaptable memory device enclosure that can accommodate memory devices of different form factors having different widths for quick and convenient installation, and advantageously redirect the air flow to the narrower form factor for effective cooling during testing or under normal operation of the memory device. Device shrouds can be used in conjunction with device interface boards (DIBs) and similar components used to test memory devices and computer hardware, or can be used within a housing or enclosure as a consumer electronic product to cool consumer memory devices.

At least one technical advantage of the disclosed techniques is that cold air can be received by the shrouds from a cooling system, and the shrouds can direct the cold air over surfaces of a memory device housed therein, which improves operating performance and reliability. Furthermore, the shrouds in one embodiment can be produced by a 3D printer which reduces costs and improves accessibility. Micro fans can be placed at the top and/or bottom of the shrouds to force cool air over the surfaces of the device, which further improves the cooling of memory devices.

1. In some embodiments, an apparatus for housing and cooling a memory device comprises a device shroud operable to receive the memory device and to guide air over the memory device to cool the memory device during operation thereof, and a cooling system comprising a first fan disposed on a bottom surface of the device shroud and operable to blow air into the device shroud, wherein the air is guided over a surface of the memory device by the device shroud, and a second fan disposed on a top surface of the device shroud and operable to blow the air out of the device shroud.
2. The apparatus of claim 1, wherein the device shroud is further operable to receive a memory device comprising one of a double-width device, and a single-width device with a device adapter.
3. The apparatus of claim 2, wherein the single-width device comprises an E3.S 1T device, and the double-width device comprises an E3.S 2T device.
4. The apparatus of claim 1, further comprising a device housing operable to house the device shroud, wherein the device housing comprises a display device operable to display a temperature of the memory device, and a plurality of user control inputs operable to control operation of the cooling system.
5. The apparatus of claim 1, wherein the memory device comprises a temperature sensor, and wherein the cooling system is operable to cool the memory device according to a measurement of the temperature sensor.
6. The apparatus of claim 1, wherein the device shroud comprises electrostatic discharge (ESD) materials.
7. The apparatus of claim 1, wherein the device shroud is 3D printed.
8. The apparatus of claim 1, wherein the memory device comprises a solid state drive (SSD).
9. In some embodiments, an apparatus for housing and cooling a memory device comprises a device shroud operable to receive the memory device and to guide air over the memory device to cool the memory device during operation thereof, wherein a front of the device shroud comprises an opening operable to intake air from outside the device shroud, and wherein the device shroud comprises internal fins operable to guide air longitudinally along the memory device, and a cooling system comprising a first fan disposed on a first surface of the device shroud and operable to blow air out of the device shroud, and a second fan disposed on a second surface of the device shroud and operable to blow air out of the device shroud.
10. The apparatus of claim 9, wherein the device shroud is further operable to receive a memory device comprising one of a double-width device, and a single-width device with a device adapter.
11. The apparatus of claim 10, wherein the single-width device is approximately 7.5 mm wide, and wherein the double-width device is approximately 16.8 mm wide.
12. The apparatus of claim 9, further comprising a device housing operable to house the device shroud, wherein the device housing comprises a display device operable to display a temperature of the memory device, and a plurality of user control inputs operable to control operation of the cooling system, and wherein further the first surface is a top surface and the second surface is a bottom surface.
13. The apparatus of claim 9, wherein the memory device comprises a temperature sensor, and wherein the cooling system is operable to cool the memory device according to a measurement of the temperature sensor.
14. The apparatus of claim 9, wherein the device shroud comprises electrostatic discharge (ESD) materials.
15. The apparatus of claim 9, wherein the device shroud is 3D printed.
16. The apparatus of claim 9, wherein the memory device comprises a solid state drive (SSD).
17. In some embodiments, a consumer electronic product for housing and cooling a memory device comprises a housing comprising a display device operable to display a temperature of the memory device, and a plurality of user control buttons, a device shroud disposed within the housing and operable to secure the memory device within the housing and to guide air over a surface of the memory device to cool the memory device during operation, and a cooling system operable to cool the memory device according to input received via the user control buttons, the cooling system comprising a first fan disposed on a top surface of the housing, and a second fan disposed on a bottom surface of the housing, wherein the first and second fans are operable to cool the memory device during operation thereof.
18. The consumer electronic product of claim 17, wherein the device shroud and the housing comprise a front air intake, wherein the first fan is further operable to blow air upward and out of the device shroud, wherein the second fan is further operable to blow air downward and out of the device shroud, wherein the first fan and second fan are further operable to exhaust hot air out of the device shroud to cool the memory device, and wherein the device shroud comprises internal fins operable to guide air longitudinally along the memory device.
19. The consumer electronic product of claim 17, wherein the first fan is further operable to blow air upward and out of the device shroud to exhaust hot air, and wherein the second fan is further operable to blow air upward and into the device shroud to cool the memory device.
20. The consumer electronic product of claim 17, wherein the device shroud is further operable to receive a memory device comprising one of a double-width device, and a single-width device with a device adapter.

Any and all combinations of any of the claim elements recited in any of the claims and/or any elements described in this application, in any fashion, fall within the contemplated scope of the present invention and protection.

The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments.

Aspects of the present embodiments may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a “module,” a “system,” or a “computer.” In addition, any hardware and/or software technique, process, function, component, engine, module, or system described in the present disclosure may be implemented as a circuit or set of circuits. Furthermore, aspects of the present disclosure may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

Aspects of the present disclosure are described above with reference to flowchart illustrations and/or block diagrams of methods, apparatus (systems) and computer program products according to embodiments of the disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine. The instructions, when executed via the processor of the computer or other programmable data processing apparatus, enable the implementation of the functions/acts specified in the flowchart and/or block diagram block or blocks. Such processors may be, without limitation, general purpose processors, special-purpose processors, application-specific processors, or field-programmable gate arrays.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions. While the preceding is directed to embodiments of the present disclosure, other and further embodiments of the disclosure may be devised without departing from the basic scope thereof, and the scope thereof is determined by the claims that follow.

Embodiments of the present invention are thus described. While the present invention has been described in particular embodiments, it should be appreciated that the present invention should not be construed as limited by such embodiments, but rather construed according to the following claims.

What is claimed is:

1. An apparatus for housing and cooling a memory device, the apparatus comprising:
a device shroud operable to receive the memory device and to guide air over the memory device to cool the memory device during operation thereof; and
a cooling system comprising:
a first fan disposed on a bottom surface of the device shroud and operable to blow air into the device shroud, wherein the air is guided over a surface of the memory device by the device shroud; and
a second fan disposed on a top surface of the device shroud and operable to blow the air out of the device shroud.

2. The apparatus of claim 1, wherein the device shroud is further operable to receive a memory device comprising one of: a double-width device; and a single-width device with a device adapter.

3. The apparatus of claim 2, wherein the single-width device comprises an E3.S 1T device, and the double-width device comprises an E3.S 2T device.

4. The apparatus of claim 1, further comprising a device housing operable to house the device shroud, wherein the device housing comprises: a display device operable to display a temperature of the memory device; and a plurality of user control inputs operable to control operation of the cooling system.

5. The apparatus of claim 1, wherein the memory device comprises a temperature sensor, and wherein the cooling system is operable to cool the memory device according to a measurement of the temperature sensor.

6. The apparatus of claim 1, wherein the device shroud comprises electrostatic discharge (ESD) materials.

7. The apparatus of claim 1, wherein the device shroud is 3D printed.

8. The apparatus of claim 1, wherein the memory device comprises a solid state drive (SSD).

9. An apparatus for housing and cooling a memory device, the apparatus comprising:
a device shroud operable to receive the memory device and to guide air over the memory device to cool the memory device during operation thereof, wherein a front of the device shroud comprises an opening operable to intake air from outside the device shroud, and wherein the device shroud comprises internal fins operable to guide air longitudinally along the memory device; and
a cooling system comprising:
a first fan disposed on a first surface of the device shroud and operable to blow air out of the device shroud; and
a second fan disposed on a second surface of the device shroud and operable to blow air out of the device shroud.

10. The apparatus of claim 9, wherein the device shroud is further operable to receive a memory device comprising one of: a double-width device; and a single-width device with a device adapter.

11. The apparatus of claim 10, wherein the single-width device is approximately 7.5 mm wide, and wherein the double-width device is approximately 16.8 mm wide.

12. The apparatus of claim 9, further comprising a device housing operable to house the device shroud, wherein the device housing comprises: a display device operable to display a temperature of the memory device; and a plurality of user control inputs operable to control operation of the cooling system, and wherein further the first surface is a top surface and the second surface is a bottom surface.

13. The apparatus of claim 9, wherein the memory device comprises a temperature sensor, and wherein the cooling system is operable to cool the memory device according to a measurement of the temperature sensor.

14. The apparatus of claim 9, wherein the device shroud comprises electrostatic discharge (ESD) materials.

15. The apparatus of claim 9, wherein the device shroud is 3D printed.

16. The apparatus of claim 9, wherein the memory device comprises a solid state drive (SSD).

17. A consumer electronic product for housing and cooling a memory device, the product comprising:
a housing comprising:
a display device operable to display a temperature of the memory device; and
a plurality of user control buttons;
a device shroud disposed within the housing and operable to secure the memory device within the housing and to guide air over a surface of the memory device to cool the memory device during operation; and
a cooling system operable to cool the memory device according to input received via the user control buttons, the cooling system comprising:
a first fan disposed on a top surface of the housing; and
a second fan disposed on a bottom surface of the housing, wherein the first and second fans are operable to cool the memory device during operation thereof.

18. The consumer electronic product of claim 17, wherein the device shroud and the housing comprise a front air intake, wherein the first fan is further operable to blow air upward and out of the device shroud, wherein the second fan is further operable to blow air downward and out of the device shroud, wherein the first fan and second fan are further operable to exhaust hot air out of the device shroud to cool the memory device, and wherein the device shroud comprises internal fins operable to guide air longitudinally along the memory device.

19. The consumer electronic product of claim 17, wherein the first fan is further operable to blow air upward and out of the device shroud to exhaust hot air, and wherein the second fan is further operable to blow air upward and into the device shroud to cool the memory device.

20. The consumer electronic product of claim 17, wherein the device shroud is further operable to receive a memory device comprising one of: a double-width device; and a single-width device with a device adapter.
